(19) United States
(12) Patent Application Publication
(10) Pub. No.: US 2026/0023097 A1
(43) Pub. Date: Jan. 22, 2026

(54) PRESS-FIT MODULE AND PRESS-FIT TEST DEVICE

(71) Applicant: Delta Electronics, Inc., Taoyuan City (TW)

(72) Inventors: Wenpei Shu, Shanghai (CN); Kun Jiang, Shanghai (CN)

(21) Appl. No.: 19/251,138

(22) Filed: Jun. 26, 2025

(30) Foreign Application Priority Data
Jul. 18, 2024 (CN) 202410965687.6

(51) Int. Cl. G01R 1/04

(52) U.S. Cl. CPC G01R 1/0408

(57) ABSTRACT

The present disclosure provides a press-fit test device and a press-fit module. The press-fit test device is configured for testing the electrical performance and the electrical connection of an electronic device under test. The press-fit test device includes a base and a press-fit module. The press-fit module is disposed on the base. The electronic device is positioned between the press-fit module and the test module of the base. When the press-fit module presses against the electronic device, the electronic device establishes an electrical connection to the test module, thereby generating test signals and enabling the electrical performance and connection testing to be performed.

### CROSS-REFERENCE TO RELATED APPLICATION

This application claims priority to China Patent Application No. 202410965687.6, filed on Jul. 18, 2024. The entireties of the above-mentioned patent application are incorporated herein by reference for all purposes.

### FIELD OF THE INVENTION

The present disclosure relates to a technical field of electronic component testing, and more particularly to a press-fit module and a press-fit test device.

### BACKGROUND OF THE INVENTION

With the trend toward miniaturization in power electronic systems, integrated electronic modules have experienced rapid development. Correspondingly, testing devices for integrated electronic modules have also advanced rapidly. For the electronic module under test, a test socket serves as a crucial testing apparatus. The test socket functions as a connector socket positioned between the electronic module under test and a circuit board, and is configured to enable a stable connection between pins of the electronic module and the circuit board (i.e., a test mainboard), which facilitates testing the electrical performance and connectivity of the electronic module under test.

A traditional test socket includes a press-fit cover, a base, and a plurality of test probes. The plurality of test probes are disposed on the base. The electronic module under test is disposed on the base. The press-fit cover is used to press against the electronic module under test, thereby pressing it onto the base. During the testing process, the user applies force to the press-fit cover, causing the press-fit cover to press against the electronic module. As a result, pins of the electronic module are in contact with the multiple test probes on the base, ensuring stable contact between the electronic module and the test socket during the testing process, thereby enabling the execution of the test operation.

However, as current electronic modules evolve toward higher power applications, the number of pins in the integrated electronic modules is gradually increased, and the number of test probes of the test socket is increased accordingly. Consequently, users are required to apply greater force to the press-fit cover, the traditional test sockets are difficult to effectively address this issue.

Therefore, there is a need of providing a press-fit module and a press-fit test device to obviate the drawbacks encountered from the prior arts.

### SUMMARY OF THE INVENTION

It is an objective of the present disclosure to provide a press-fit module and a press-fit test device, which achieves the advantages of reducing the required torque, enhancing testing stability, and improving accuracy.

In accordance with an aspect of the present disclosure, there is provided a press-fit module. The press-fit module includes a rotating handle, a carrier device, and a pressing structure. The carrier device includes a holder frame. The holder frame includes a base, a shaft portion, and a through hole. The shaft portion is disposed on an upper base surface of the base, and the through hole penetrates through the shaft portion. The rotating handle covers the shaft portion. The pressing structure includes a cam follower and a cam pushing unit. The cam follower includes a rotating disk and a connecting shaft. At least two rollers are disposed on a lower disk surface of the rotating disk. The connecting shaft is connected to the rotating handle through the through hole. The cam pushing unit is movably connected to the lower disk surface, and includes a plate body and at least two guide structures. The at least two guide structures are disposed on an upper plate body surface of the plate body, and are corresponded to the at least two rollers, respectively. Each guide structure includes a sequential connection of a first flat structure, an inclined structure, and a second flat structure. When the rotating handle is rotated, the rotating handle drives the cam follower to rotate accordingly, each roller of the cam follower rolls from the first flat structure of the corresponding guide structure to the second flat structure via the inclined structure, thereby pushing the cam pushing unit to move in the direction away from the cam follower.

In accordance with another aspect of the present disclosure, there is provided a press-fit test device for testing an electronic device. The press-fit test device includes a mount and a press-fit module. The mount includes a test module. The press-fit module is disposed on the mount and includes a rotating handle, a carrier device, and a pressing structure. The carrier device includes a holder frame. The holder frame includes a base, a shaft portion, and a through hole. The shaft portion is disposed on an upper base surface of the base, and the through hole penetrates through the shaft portion. The rotating handle covers the shaft portion. The pressing structure includes a cam follower and a cam pushing unit. The cam follower includes a rotating disk and a connecting shaft. At least two rollers are disposed on a lower disk surface of the rotating disk. The connecting shaft is connected to the rotating handle through the through hole. The cam pushing unit is movably connected to the lower disk surface, and includes a plate body and at least two guide structures. The at least two guide structures are disposed on an upper plate body surface of the plate body, and are corresponded to the at least two rollers, respectively. Each guide structure includes a sequential connection of a first flat structure, an inclined structure, and a second flat structure. When the rotating handle is rotated, the rotating handle drives the cam follower to rotate accordingly, each roller of the cam follower rolls from the first flat structure of the corresponding guide structure to the second flat structure via the inclined structure, thereby pushing the cam pushing unit to move in the direction away from the cam follower. The electronic device is positioned between the press-fit module and the test module. When the cam pushing unit moves away from the cam follower, the cam pushing unit applies a pressing force to the electronic device, forcing the electronic device against the test module to establish an electrical connection, thereby generating test signals and enabling test execution of the electronic device.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a perspective view illustrating a press-fit test device of an embodiment of the present disclosure mounted on a circuit board;

FIG. 2 is an exploded view of the press-fit test device of FIG. 1;

FIG. 3 is another exploded view of the press-fit test device of FIG. 1 from a different angle;

FIG. 4 is a cross-sectional view of the press-fit test device of FIG. 1;

FIG. 5 is a side view of a cam pushing unit and a cam follower of the press-fit test device of FIG. 1;

FIG. 6 is a side view of the cam pushing unit and the cam follower of the press-fit test device of FIG. 5, wherein the cam follower is rotated at a specific angle;

FIG. 7 is a perspective view of a rotating handle of the press-fit test device of FIG. 1, wherein a handle component of the rotating handle is unfolded as a second state;

FIG. 8 is another perspective view of a rotating disc of the press-fit test device of FIG. 7, wherein the handle component of the rotating handle is folded as a first state;

FIG. 9 is a partial cross-sectional view of the press-fit test device of FIG. 1;

FIG. 10 is a partial cross-sectional view of a region X of the press-fit test device of FIG. 4;

FIG. 11 is a partial cross-sectional view of a region Y of the press-fit test device of FIG. 4; and

FIG. 12 is a partial cross-sectional view of a region Z of the press-fit test device of FIG. 4.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “front,” “rear,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items. The following is a detailed description of some embodiments of the present disclosure in conjunction with the accompanying drawings. In the absence of conflict, the following embodiments and some features in the embodiments may be combined with each other. The same or similar concepts or processes may not be described in detail in some embodiments.

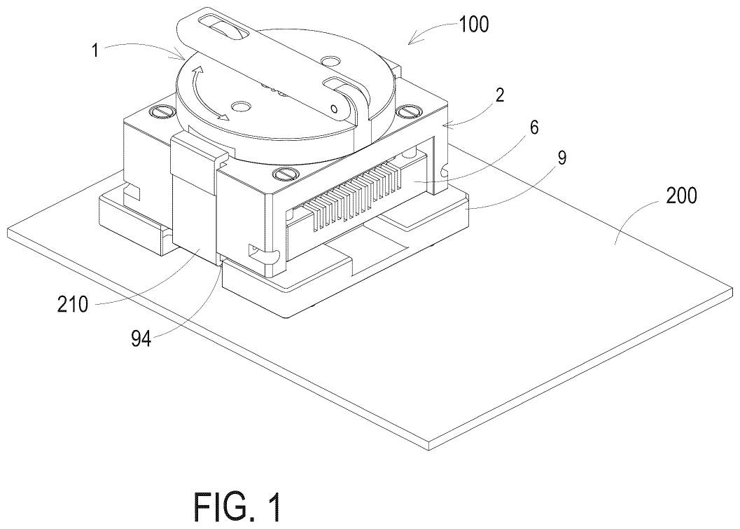

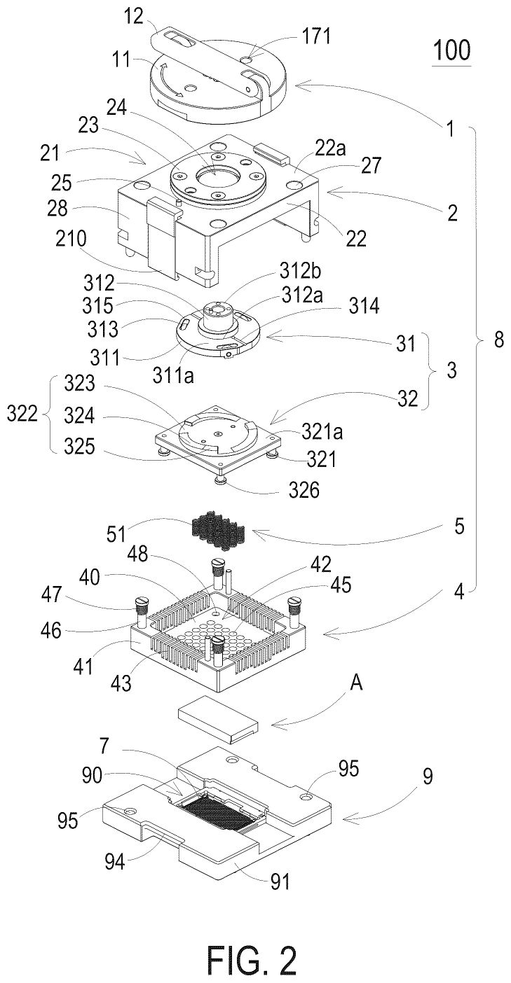

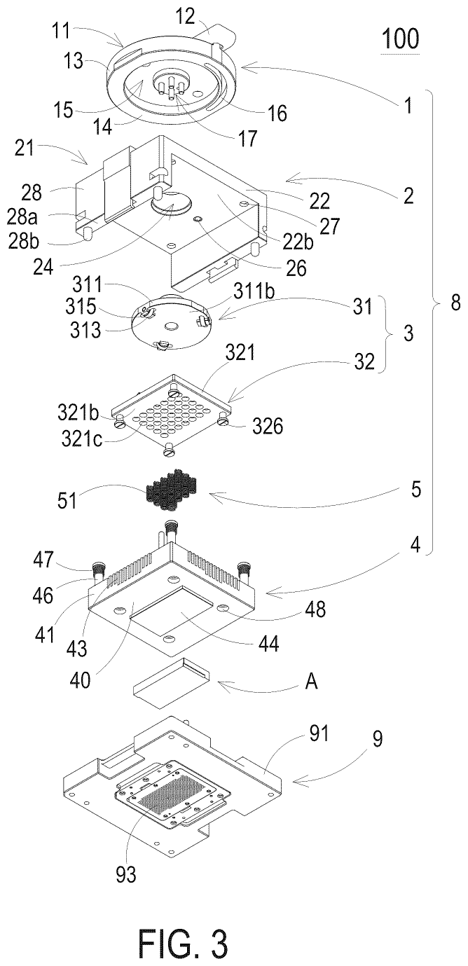

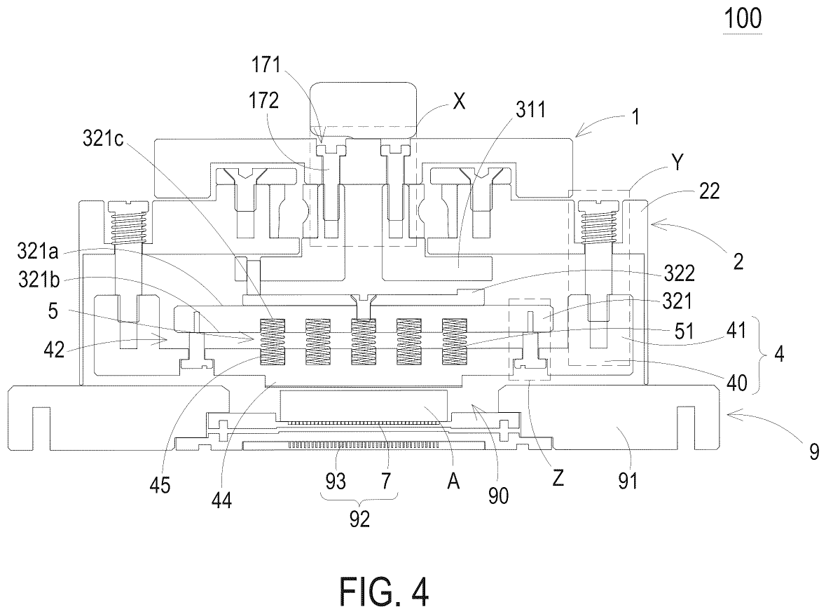

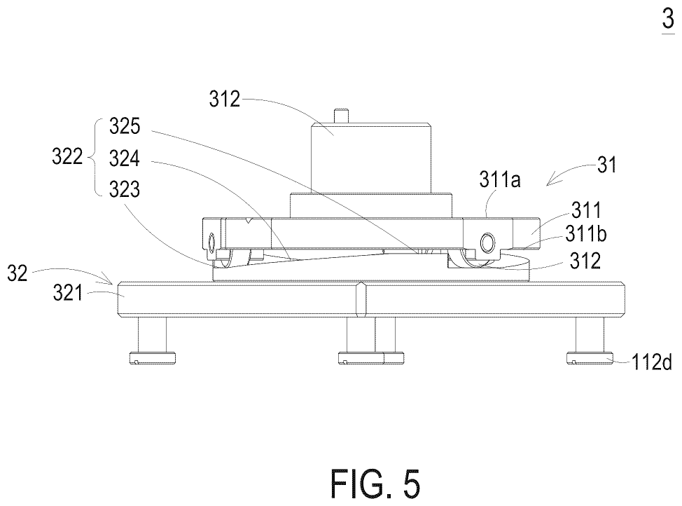

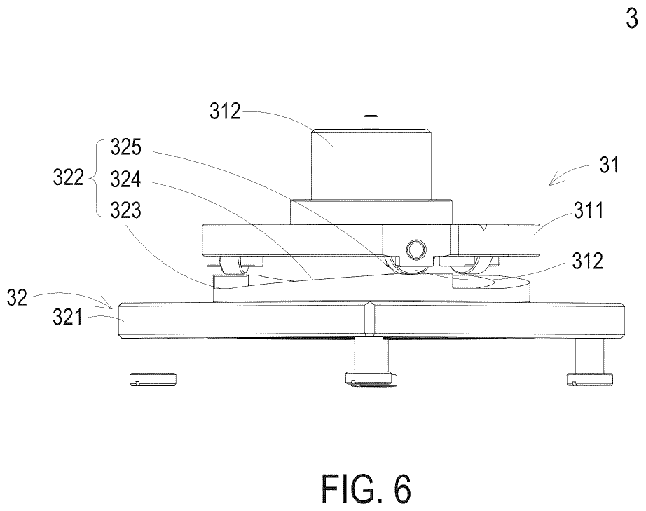

FIG. 1 is a perspective view illustrating a press-fit test device of an embodiment of the present disclosure mounted on a circuit board, FIG. 2 is an exploded view of the press-fit test device of FIG. 1, FIG. 3 is another exploded view of the press-fit test device of FIG. 1 from a different angle, FIG. 4 is a cross-sectional view of the press-fit test device of FIG. 1, FIG. 5 is a side view of a cam pushing unit and a cam follower of the press-fit test device of FIG. 1, and FIG. 6 is a side view of the cam pushing unit and the cam follower of the press-fit test device of FIG. 5, wherein the cam follower is rotated at a specific angle. As shown in FIG. 1 to FIG. 6, the press-fit test device 100 of the present disclosure is mounted on a circuit board 200 and is configured to test the electrical performance and connectivity of an electronic device under test (EDUT) A. The press-fit test device 100 includes a press-fit module 8 and a mount 9. The press-fit module 8 is disposed on the mount 9. The mount 9 includes a test module 92. The EDUT A is disposed between the press-fit module 8 and the test module 92. The press-fit module 8 is configured to apply a pressing force to the EDUT A, and the EDUT A is pressed against the test module 92 to establish an electrical connection, thereby generating test signals and establish execution of the electrical performance and connectivity testing of the EDUT A.

As shown in FIG. 2 and FIG. 3, in the present embodiment, the press-fit module 8 includes a rotating handle 1, a carrier device 2, and a pressing structure 3. The carrier device 2 includes a holder frame 21. The holder frame 21 includes a base 22, a shaft portion 23, and a through hole 24. The base 22 has an upper base surface 22a and a lower base surface 22b disposed oppositely. The upper base surface 22a faces the rotating handle 1. The shaft portion 23 is disposed on the upper base surface 22a, and the through hole 24 penetrates through the shaft portion 23. The rotating handle 1 covers the shaft portion 23, i.e., the rotating handle 1 wraps around and closely engages with the shaft portion 23, so that the rotating handle 1 can be rotated on the shaft portion 23 when a force is applied.

As shown in FIG. 2 and FIG. 3, in the present embodiment, the pressing structure 3 includes a cam follower 31 and a cam pushing unit 32. The cam follower 31 includes a rotating disk 311 and a connecting shaft 312. The rotating disk 311 includes an upper disk surface 311a and a lower disk surface 311b disposed oppositely. The lower disk surface 311b faces the cam pushing unit 32. At least two rollers 313 are disposed on the lower disk surface 311b of the rotating disk 311. A first end 312a of the connecting shaft 312 is connected to the rotating disk 311, and a second end 312b of the connecting shaft 312 penetrates through the through hole 24 of the holder frame 21 and is detachably connected to the rotating handle 1. Therefore, when the rotating handle 1 is rotated by a force, the cam follower 31 is driven to rotate accordingly. The cam pushing unit 32 includes a plate body 321 and at least two guide structures 322. The plate body 321 has an upper plate body surface 321a and a lower plate body surface 321b disposed oppositely. The upper plate body surface 321a faces the cam follower 31. The at least two guide structures 322 are disposed on the upper plate body surface 321a, and are aligned with the respective rollers 313 of the cam follower 31, respectively, so that the rollers 313 can move along corresponding guide structures 322. In the present embodiment, each guide structure 322 includes a sequential connection of a first flat structure 323, an inclined structure 324, and a second flat structure 325 connected in sequence. A height difference is formed between the horizontal plane where the first flat structure 323 is located and the horizontal plane where the second flat structure 325 is located. Two ends of the inclined structure 324 are in connection with the first flat structure 323 and the second flat structure 325, respectively. In the present embodiment, the number of rollers 313 of the cam follower 31 corresponds to the number of guide structures 322 of the cam pushing unit 32, for example, three respectively, but are not limited thereto.

In the present embodiment, when the rotating handle 1 is rotated by a force, the rotating handle 1 drives the cam follower 31 to rotate accordingly. At the same time, the rollers 313 of the cam follower 31 abut against the corresponding guide structures 322 disposed on the plate body 321 of the cam pushing unit 32. Each roller 313 of the cam follower 31 rolls from the first flat structure 323 of the corresponding guide structure 322 (as shown in FIG. 5) to the second flat structure 325 (as shown in FIG. 6) via the inclined structure 324, thereby pushing the cam pushing unit 32 to move in the direction toward the mount 9. As a result, the EDUT A is press-fitted against the mount 9, and a plurality of pins of the EDUT A stably contact a plurality of test probes 7. Accordingly, test signals can be transmitted between the EDUT A and the circuit board 200 via the plurality of test probes 7, thereby enabling the testing of the electrical performance of the EDUT A. By comparing with the conventional press-fit structures, the cooperation between the cam follower 31 and the cam pushing unit 32 in the present disclosure converts sliding friction in the press-fit process into rolling friction, which significantly reduces the required torque, and the advantages of improving testing stability and accuracy are achieved.

As shown in FIG. 2, FIG. 3, and FIG. 4, in the present embodiment, the press-fit module 8 includes a heat dissipation device 4. The heat dissipation device 4 is movably connected to the holder frame 21 and is disposed between the mount 9 and the holder frame 21. The plate body 321 of the cam pushing unit 32 is disposed adjacent to the heat dissipation device 4. When the cam follower 31 pushes against the cam pushing unit 32 to move, the cam pushing unit 32 pushes the heat dissipation device 4 to move relative to the holder frame 21. Consequently, the heat dissipation device 4 presses the EDUT A in the direction toward the mount 9 for press-fitting.

As shown in FIG. 2, FIG. 3, and FIG. 4, in the present embodiment, the press-fit module 8 includes an elastic component 5. The elastic component 5 includes a plurality of first elastic elements 51, which are disposed in an array between the cam pushing unit 32 and the heat dissipation device 4, so as to assist the cam pushing unit 32 in uniformly pushing the heat dissipation device 4. As a result, the heat dissipation device 4 stably and evenly applies force to press the EDUT A, thereby achieving the advantages of improving testing stability and accuracy. Preferably but not exclusively, the first elastic elements 51 are springs.

As shown in FIG. 2 to FIG. 4, in the present embodiment, the mount 9 includes a main body 91 and a test module 92. The main body 91 includes a second accommodating space 90. The test module 92 includes the plurality of test probes 7 and a test board 93. The test module 92 is disposed at the bottom of the second accommodating space 90, and the plurality of test probes 7 are disposed in an array within the second accommodating space 90. The second accommodating space 90 of the main body 91 is configured to accommodate the EDUT A. The plurality of test probes 7 are electrically connected to the test board 93 and are configured to contact the plurality of pins (not shown) of the EDUT A. In the present embodiment, the holder frame 21 of the carrier device 2 includes a first latching element 210. The mount 9 includes a second latching element 94. The first latching element 210 engages with the second latching element 94, thereby allowing the carrier device 2 to be detachably assembled with the mount 9 (as shown in FIG. 1). In some embodiments, the test probes 7 are test pins, resilient contacts, or a combination thereof, but are not limited thereto.

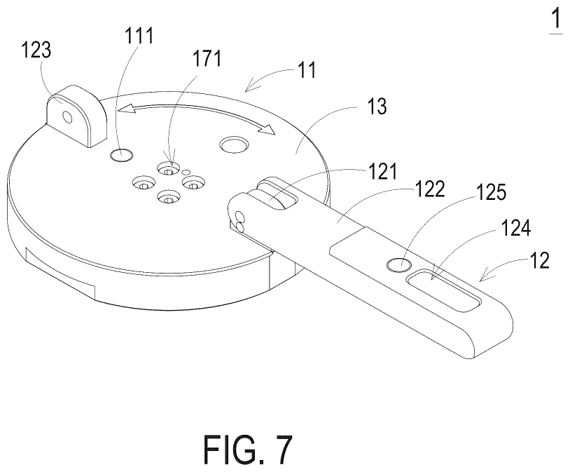

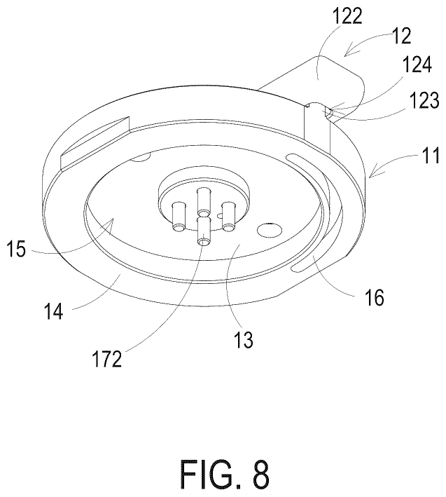

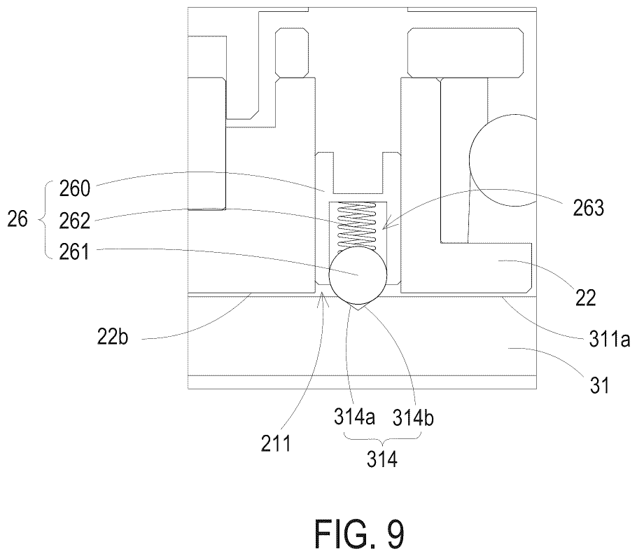

FIG. 7 is a perspective view of a rotating handle of the press-fit test device of FIG. 1, wherein a handle component of the rotating handle is unfolded as a second state. FIG. 8 is another perspective view of a rotating disc of the press-fit test device of FIG. 7, wherein the handle component of the rotating handle is folded as a first state. As shown in FIG. 2, FIG. 3, FIG. 8, and FIG. 9, in the present embodiment, the rotating handle 1 includes a rotating disk 11 and a handle component 12. The rotating disk 11 includes a top wall 13, a side wall 14, a recessed portion 15, a track groove 16, and a connecting component 17. The handle component 12 is disposed on the top wall 13. The recessed portion 15 is formed in the bottom of the rotating disk 11 and is defined by the top wall 13 and the side wall 14. The profile of the recessed portion 15 matches the profile of the shaft portion 23 of the holder frame 21. In other words, the recessed portion 15 covers the shaft portion 23, and the recessed portion 15 and the shaft portion 23 are tightly connected. Consequently, the recessed portion 15 of the rotating handle 1 is fitted over the shaft portion 23 of the holder frame 21, allowing the rotating handle 1 to rotate along the shaft portion 23 as an axis. The track groove 16 is formed in the bottom of the side wall 14 and extends in a circumferential direction. The connecting component 17 is disposed on the recessed portion 15.

Please also refer to FIG. 2, FIG. 3, FIG. 7, and FIG. 8. In the present embodiment, the handle component 12 includes a rotation shaft 121, a grip 122, and a first locking element 123. The rotation shaft 121 is disposed on the top wall 13. The first locking element 123 is disposed on the top wall 13, and spaced apart from the rotation shaft 121 by a predetermined distance. A first end of the grip 122 is movably connected to the rotation shaft 121, allowing the grip 122 to rotate along the rotation shaft 121 as the axis. A second end of the grip 122 is a free end and includes a second locking element 124. In the present embodiment, the grip 122 is switchable between a folded first state and an unfolded second state. In the first state, the second locking element 124 at the second end of the grip 122 engages with the first locking element 123, thereby fixing the grip 122 on the rotating disk 11 in a manner parallel to a surface of the top wall 13. In the second state, the second locking element 124 at the second end of the grip 122 is disengaged from the first locking element 123, allowing the grip 122 to rotate along the rotation shaft 121 as the axis, and the second end of the grip 122 is pivoted outward from the rotating disk 11, so as to facilitate force application by the user. In an embodiment, the first locking element 123 is a locking protrusion, and the second locking element 124 is a locking opening. The locking opening penetrates through the second end of the grip 122. As shown in FIG. 8, when the grip 122 is in the folded first state, the second locking element 124 at the second end of the grip 122 rotates to engage with the first locking element 123, i.e., the locking protrusion engages with the locking opening, thereby securing two ends of the grip 122 to the surface of the top wall 13 of the rotating disk 11. Consequently, the advantage of preventing damage to the rotation shaft 121 during the rotating process is achieved. As shown in FIG. 7, when the grip 122 is in the unfolded second state, the second locking element 124 at the second end of the grip 122 is separated from the first locking element 123, and flipped to the outside of the rotating disk 11. When the grip 122 is in the second state, the user may grasp the second end of the grip 122 to apply force, thereby rotating the rotating handle 1 to drive the cam follower 31 to rotate synchronously. Under this circumstance, since the grip 122 extends outwardly, the increased force arm length enables the user to press the EDUT A with reduced force, effectively enhancing test stability and accuracy.

As shown in FIG. 7 and FIG. 8, in the present embodiment, the rotating disk 11 includes a first magnetic element 111. The first magnetic element 111 is disposed on the top wall 13 of the rotating disk 11. The grip 122 includes a second magnetic element 125 corresponding to the first magnetic element 111. When the second locking element 124 at the second end of the grip 122 is rotated to engage with the first locking element 123, the first magnetic element 111 of the rotating disk 11 is magnetically coupled with the second magnetic element 125 of the grip 122. Consequently, the second end of the grip 122 is securely fixed to the top wall 13 of the rotating disk 11.

As shown in FIG. 2, FIG. 3, and FIG. 8, in the present embodiment, the carrier device 2 includes a guide post 25. The guide post 25 is disposed on the upper base surface 22a and is positioned adjacent to the shaft portion 23. The guide post 25 is pluggably accommodated in the track groove 16 of the rotating handle 1, configured to guide the rotation of the rotating handle 1 and limit the range of the rotation angle of the rotating handle 1. Consequently, the cam follower 31 is prevented from excessive rotation, avoiding over-pressing or rebound of the cam push unit 32.This reduces damage risk to the EDUT A and enhances test stability.

As shown in FIG. 2 and FIG. 3, the rotating disk 311 of the cam follower 31 includes at least two openings 315. The at least two openings 315 penetrate the upper disk surface 311a and the lower disk surface 311b. The number of openings 315 corresponds to the number of rollers 313, but not limited thereto. In the present embodiment, the number of openings 315 is three. Each roller 313 is rotatably disposed within a corresponding opening 315, and at least a portion of the roller 313 is protruded from the lower disk surface 311b of the rotating disk 311 through the opening 315, so that the roller 313 abuts against the corresponding guide structure 322 of the cam pushing unit 32. The arrangement of the rollers 313 within the openings 315 reduces the overall height of the device, thus achieving volume reduction.

As shown in FIG. 2 to FIG. 4, the heat dissipation device 4 includes a bottom plate 40 and a plurality of side walls 41. The plurality of side walls 41 are disposed around the bottom plate 40, and a first accommodating space 42 is defined by the bottom plate 40 and the plurality of side walls 41. The cam pushing unit 32 is movably disposed within the first accommodating space 42. The heat dissipation device 4 includes a plurality of heat dissipation fins 43. The plurality of heat dissipation fins 43 are disposed on the plurality of side walls 41, respectively. Due to the arrangement of the heat dissipation fins 43, the heat dissipation area is increased, thereby enhancing heat dissipation efficiency. As shown in FIG. 3 and FIG. 4, in the present embodiment, the heat dissipation device 4 includes a protruding portion 44. The protruding portion 44 is disposed on the bottom surface of the bottom plate 40, and corresponds to the EDUT A. The protruding portion 44 is configured to abut against the EDUT A. In an embodiment, an area of the bottom surface of the protruding portion 44 is greater than or equal to an area of the top surface of the EDUT A, so that the EDUT A is uniformly contacted and pressed by the protruding portion 44, thereby ensuring the stability of the testing process.

As shown in FIG. 2 to FIG. 4, the plate body 321 of the cam pushing unit 32 includes a plurality of first recesses 321c, which are disposed in an array on the lower plate body surface 321b. The heat dissipation device 4 includes a plurality of second recesses 45, which are disposed in an array on the bottom plate 40. As shown in FIG. 4, an end of each of the plurality of first elastic elements 51 abuts against the corresponding first recess 321c of the cam pushing unit 32, and the other end of each first elastic element 51 abuts against the corresponding second recess 45 of the heat dissipation device 4, thereby positioning each of the first elastic elements 51. The plurality of first elastic elements 51 provide elastic support between the cam pushing unit 32 and the heat dissipation device 4. When the cam pushing unit 32 is pushed in the direction toward the EDUT A, the cam pushing unit 32 presses against the heat dissipation device 4 through the plurality of first elastic elements 51, so that the heat dissipation device 4 is driven to move relative to the holder frame 21. At the same time, the bottom plate 40 of the heat dissipation device 4 presses the EDUT A toward the mount 9 for press-fitting, thereby allowing the EDUT A to be uniformly stressed and enhancing the stability and accuracy of the test. FIG. 9 is a partial cross-sectional view of the press-fit test device of FIG. 1. As shown in FIGS. 2, 3, 4, and 9, in this embodiment, the carrier device 2 includes at least one first positioning element 26. The at least one first positioning element 26 is disposed on the lower base surface 22b. The cam follower 31 includes at least one second positioning element 314, which is disposed on the upper disk surface 311a and disposed along the circumference of the connecting shaft 312. By engaging the first positioning element 26 with the corresponding second positioning element 314, the cam follower 31 is positioned to the carrier device 2, and the rotation of the cam follower 31 is limited. In the present embodiment, preferably but not limited, the first positioning element 26 is a positioning ball, and the second positioning element 314 is a positioning groove. The number of the first positioning elements 26 is equal to the number of the second positioning elements 314, for example two of each. It is noted that the numbers of the first positioning elements 26 and the second positioning elements 314 are not limited to the above embodiment, and can be adjusted according to practical requirements. In the present embodiment, when a user rotates the rotating handle 1 to drive the cam follower 31 to rotate, the at least one first positioning element 26 of the holder frame 21 contacts the upper disk surface 311a of the cam follower 31 and rolls on the upper disk surface 311a until the first positioning element 26 engages with the corresponding second positioning element 314. Accordingly, the cam follower 31 is positioned on the holder frame 21, and the cam follower 31 is prevented from rotating relative to the holder frame 21. Consequently, the cam follower 31 is prevented from rotating in the reversed direction, thereby ensuring stability during the testing process.

As shown in FIG. 2, FIG. 3, FIG. 4, and FIG. 9, in the present embodiment, the carrier frame 21 of the carrier device 2 includes at least one opening 211. The number of openings 211 corresponds to the number of first positioning elements 26, but not limited thereto. The openings 211 are disposed on the lower base surface 22b of the carrier frame 21. Each first positioning element 26 is disposed in corresponding one of the openings 211. Preferably but not exclusively, the first positioning element 26 is a positioning ball. Each first positioning element 26 (i.e., positioning ball) includes a cylinder 260, a ball 261, and a second elastic element 262. The cylinder 260 is tightly fitted into the opening 211, and includes an accommodating recess 263. The accommodating recess 263 is configured to accommodate the second elastic element 262 and at least a portion of the ball 261. In an embodiment, preferably but not exclusively, the ball 261 is a rollable spherical structure, and the second elastic element 262 is a compressible spring. The second elastic element 262 is disposed within the accommodating recess 263 of the cylinder 260, and is elastically connected between the bottom of the accommodating recess 263 and the ball 261. At least a portion of the ball 261 protrudes from the opening 211 of the accommodating recess 263 and extends beyond the opening 211 of the carrier frame 21. Since the second elastic element 262 is elastically connected between the bottom of the accommodating recess 263 and the ball 261, the ball 261 continuously press against the upper disk surface 311a of the cam follower 31 during the rolling process. When the ball 261 rolls to the position of the second positioning element 314, the elastic force of the second elastic element 262 pushes the ball 261 toward the second positioning element 314, so that the ball 261 is engaged with the second positioning element 314, and the cam follower 31 is positioned.

As shown in FIG. 9, in the present embodiment, the second positioning element 314 is a positioning recess, preferably. The second positioning element 314 includes a first inclined surface 314a and a second inclined surface 314b. The first inclined surface 314a and the second inclined surface 314b form a V-shaped groove structure. When the first positioning element 26 moves from the upper disk surface 311a of the cam follower 31 to the second positioning element 314, the elastic force of the second elastic element 262 of the first positioning element 26 pushes the ball 261 toward the second positioning element 314, and the ball 261 presses against the first inclined surface 314a and the second inclined surface 314b simultaneously, enhancing the stability of the positioning. In some embodiments, preferably but not exclusively, the first inclined surface 314a and the second inclined surface 314b are flat surfaces or curved surfaces, respectively.

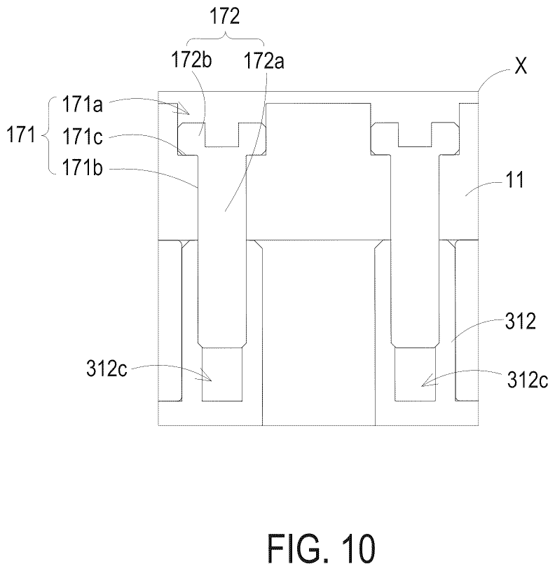

FIG. 10 is a partial cross-sectional view of a region X of the press-fit test device of FIG. 4. As shown in FIGS. 2, 3, 4, 7, 8, and 10, in the present embodiment, the connecting component 17 of the rotating disk 11 of the rotating handle 1 includes a plurality of connecting holes 171 and a plurality of fastening elements 172. In the present embodiment, the number of connecting holes 171 and the number of fastening elements 172 are four, respectively, but not limited thereto. The plurality of connecting holes 171 penetrate through the rotating disk 11, respectively. Each of the connecting holes 171 includes a first segment 171a, a second segment 171b, and an abutment surface 171c. The diameter of the first segment 171a is greater than the diameter of the second segment 171b. The abutment surface 171c is disposed between the first segment 171a and the second segment 171b. Each fastening element 172 includes a rod portion 172a and a head portion 172b, which are integrally connected. The diameter of the head portion 172b is greater than the diameter of the rod portion 172a. The rod portion 172a of each fastening element 172 extends through the corresponding connecting hole 171 from the top surface of the rotating disk 11 toward the recessed portion 15. A part of the rod portion 172a is disposed in the second segment 171b of the connecting hole 171 and extends in a direction away from the rotating disk 11. The head portion 172b of the fastening element 172 is disposed on the first segment 171a, and abuts against the abutment surface 171c. In the present embodiment, the connecting shaft 312 of the cam follower 31 includes a plurality of locking holes 312c. In the present embodiment, the number of locking holes 312c is four, but not limited thereto. Each locking hole 312c is configured to receive and secure at least a portion of the rod portion 172a of corresponding one of the fastening elements 172. At least a portion of the rod portion 172a of the fastening element 172 is secured with the locking hole 312c by the male-female threaded engagement, but this is not limited thereto. By securing the rod portion 172a into the corresponding locking hole 312c of the connecting shaft 312 of the cam follower 31, the cam follower 31 is detachably assembled to the rotating disk 11.

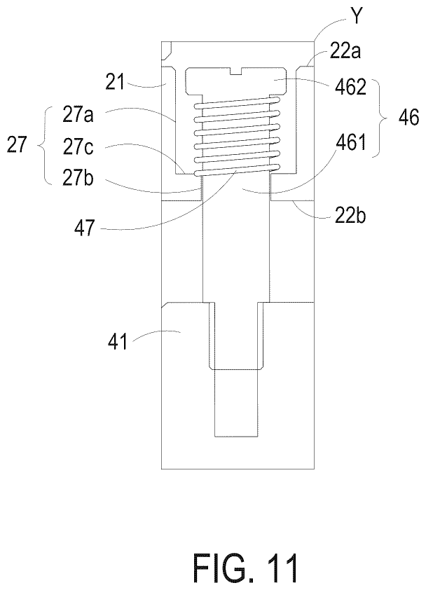

FIG. 11 is a partial cross-sectional view of a region Y of the press-fit test device of FIG. 4. As shown in FIGS. 2, 3, 4, and 11, in the present embodiment, the holder frame 21 includes a plurality of openings 27. Each opening 27 penetrates through the upper base surface 22a and the lower base surface 22b. Each opening 27 includes a first segment 27a, a second segment 27b, and an abutment surface 27c. The first segment 27a is connected between the upper base surface 22a and the second segment 27b. The second segment 27b is connected between the first segment 27a and the lower base surface 22b. The first segment 27a and the second segment 27b are cylindrical channels, and the diameter of the first segment 27a is greater than the diameter of the second segment 27b. The abutment surface 27c is formed between the first segment 27a and the second segment 27b. In the present embodiment, the heat dissipation device 4 includes a plurality of fasteners 46 and a plurality of third elastic elements 47. Each fastener 46 penetrates through corresponding one of the openings 27, and includes a rod portion 461 and a head portion 462. The rod portion 461 is for example but not limited to a cylindrical rod structure, and the diameter of the rod portion 461 is smaller than that of the second segment 27b, allowing the rod portion 461 to move inside the opening 27 along an axial direction. An end of the rod portion 461 is connected to the side wall 41 of the heat dissipation device 4, and the other end of the rod portion 461 is connected to the head portion 462. The connection between the rod portion 461 and the side wall 41 is for example but not limited to an interference fit. The head portion 462 is for example but not limited to a disc-shaped structure, and is movably disposed in the first segment 27a of the opening 27. The diameter of the head portion 462 is greater than the diameter of the second segment 27b, but smaller than that of the first segment 27a, thereby allowing the head portion 462 to move in the first segment 27a along the axial direction. The third elastic element 47 is for example but not limited to a compression spring. Each third elastic element 47 is sleeved around the rod portion 461 of the corresponding fastener 46, and disposed within the first segment 27a of the opening 27. An end of the third elastic element 47 abuts against the bottom of the head portion 462, and the other end of the third elastic element 47 abuts against the abutment surface 27c. When the cam follower 31 pushes the cam pushing unit 32 to move, the cam pushing unit 32 pushes the heat dissipation device 4 to move relative to the holder frame 21. Meanwhile, the head portions 462 of the plurality of fasteners 46 compress the third elastic elements 47 in the direction toward the abutment surfaces 27c, allowing the heat dissipation device 4 to evenly bear the pushing force, thereby enhancing testing stability and accuracy. After the testing of the electronic component A is completed, during the process of the heat dissipation device 4 returning to the original position, the elastic restoring force of the compressed third elastic elements 47 pushes the heat dissipation device 4 to move continuously and smoothly in a direction away from the mount 9. Meanwhile, the guiding structure 322 of the cam pushing unit 32 remains in contact with the roller 313 of the cam follower 31, thereby improving the accuracy of the reset process and preventing misalignment of components.

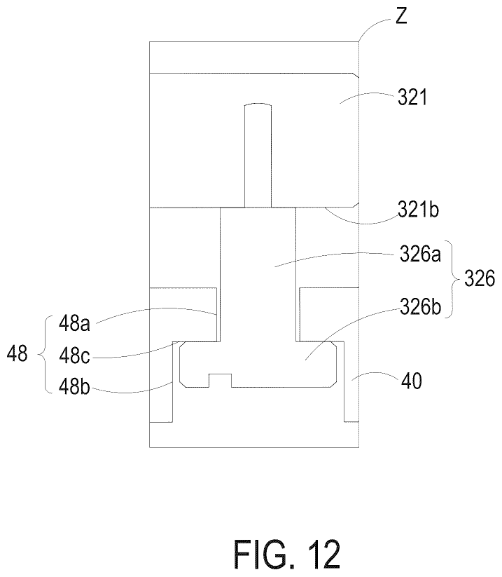

FIG. 12 is a partial cross-sectional view of a region Z of the press-fit test device of FIG. 4. As shown in FIGS. 2, 3, 4, and 12, in the present embodiment, the cam pushing unit 32 includes a plurality of first limiting elements 326, which are respectively disposed on the lower plate body surface 321b of the plate body 321. In the present embodiment, the number of first limiting elements 326 is four, but not limited thereto. The plurality of first limiting elements 326 are disposed adjacent to the four corners of the plate body 321, respectively, but not limited thereto. Each first limiting element 326 includes a rod portion 326a and a head portion 326b. The rod portion 326a is a cylindrical rod-shaped structure. An end of the rod portion 326a is connected to the head portion 326b, and the other end of the rod portion 326a is connected to the lower plate body surface 321b. The diameter of the head portion 326b is greater than the diameter of the rod portion 326a. In the present embodiment, the heat dissipation device 4 includes a plurality of second limiting elements 48, which are disposed corresponding to the plurality of first limiting elements 326. In the present embodiment, the number of second limiting elements 48 is also four, but not limited thereto. Preferably, the second limiting elements 48 are position-limiting holes, and each position-limiting hole penetrates through the bottom plate 40 and includes a first segment 48a, a second segment 48b, and an abutment surface 48c. The diameter of the first segment 48a is smaller than the diameter of the second segment 48b. The abutment surface 48c is disposed between the first segment 48a and the second segment 48b. The first limiting elements 326 of the cam pushing unit 32 are penetrated through the corresponding second limiting elements 48 of the heat dissipation device 4. At least a portion of the rod portion 326a of each first limiting element 326 is movably disposed in the first segment 48a of the second limiting element 48 (i.e., the position-limiting hole). The head portion 326b of each first limiting element 326 is movably disposed in the second segment 48b of the second limiting element 48, and is detachably abutted against the abutment surface 48c of the second limiting element 48. When the cam pushing unit 32 pushes toward the direction of the EDUT A, the end head 326b of the first limiting element 326 moves in the direction away from the abutment surface 48c within the second segment 48b of the second limiting element 48. When the cam pushing unit 32 is reset, the head portion 326b of the first limiting element 326 returns to abut against the abutment surface 48c of the second limiting element 48. Due to the configuration of the first limiting elements 326 and the second limiting elements 48, the distance between the cam pushing unit 32 and the bottom plate 40 of the heat dissipation device 4 is maintained within a specific range, thereby preventing misalignment of the EDUT A during the testing process and ensuring the stability of the test.

Please refer to FIG. 2 and FIG. 3 again. In the present embodiment, the carrier device 2 includes two extension walls 28 formed on the holder frame 21. The two extension walls 28 are respectively connected to the upper base surface 22a and the lower base surface 22b. Each extension wall 28 includes a connecting surface 28a and at least one positioning block 28b. The connecting surface 28a of each extension wall 28 is disposed toward the mount 9. The positioning block 28b is disposed on the connecting surface 28a toward the mount 9. In the present embodiment, the mount 9 includes at least one positioning hole 95. The positioning hole 95 is disposed toward the holder frame 21 and corresponds to the positioning block 28b. When the holder frame 21 is connected to the mount 9, the positioning block 28b is accommodated in the corresponding positioning hole 95, so that the holder frame 21 and the mount 9 are positioned, thereby preventing misalignment and ensuring the stability of the testing process.

From above descriptions, the present disclosure provides a press-fit test device. By the interaction of the cam follower and the cam pushing unit, the sliding friction encountered in the conventional testing devices during the press-fit process is transformed into the rolling friction, thereby reducing the required torque. In addition, the press-fit test device positions the cam follower on the holder by the ball engaging with the positioning groove, so as to prevent the cam follower from rotating in the reverse direction and ensuring the stability of the testing process. Furthermore, the rotating handle of the press-fit test device includes the foldable grip, which extends the force arm for the user, allowing the press-fit of the electronic component under test to be achieved with less applied force. Moreover, by the arrangement of the first magnetic component and the second magnetic component, the grip of the rotating handle can be stably secured onto the rotating disk. Additionally, due to the arrangement of the plurality of elastic elements of the press-fit test device, the applied force can be evenly applied onto the electronic component under test, thereby improving testing stability and accuracy.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A press-fit module, comprising:
a rotating handle;
a carrier device comprising a holder frame, wherein the holder frame comprises a base, a shaft portion, and a through hole, wherein the shaft portion is disposed on an upper base surface of the base, and the through hole penetrates through the shaft portion, wherein the rotating handle covers the shaft portion; and
a pressing structure comprising a cam follower and a cam pushing unit, wherein the cam follower comprises a rotating disk and a connecting shaft, wherein at least two rollers are disposed on a lower disk surface of the rotating disk, the connecting shaft is connected to the rotating handle through the through hole, wherein the cam pushing unit is movably connected to the lower disk surface, and comprises a plate body and at least two guide structures, wherein the at least two guide structures are disposed on an upper plate body surface of the plate body, and are corresponded to the at least two rollers, respectively, wherein each guide structure comprises a sequential connection of a first flat structure, an inclined structure, and a second flat structure;
wherein when the rotating handle is rotated, the rotating handle drives the cam follower to rotate accordingly, each roller of the cam follower rolls from the first flat structure of the corresponding guide structure to the second flat structure via the inclined structure, thereby pushing the cam pushing unit to move in the direction away from the cam follower.

2. The press-fit module according to claim 1, further comprising a heat dissipation device movably connected to the holder frame, wherein the heat dissipation device comprises a bottom plate, a plurality of side walls, a plurality of heat dissipation fins and a protruding portion, wherein the plurality of side walls are disposed around the bottom plate, and a first accommodating space is defined by the bottom plate and the plurality of side walls, wherein the cam pushing unit is disposed within the first accommodating space, the plurality of heat dissipation fins are disposed on the plurality of side walls, respectively, and the protruding portion is disposed on the bottom surface of the bottom plate.

3. The press-fit module according to claim 2, further comprising an elastic component comprising a plurality of first elastic elements, wherein the plurality of first elastic elements are disposed between the plate body of the cam pushing unit and the heat dissipation device.

4. The press-fit module according to claim 1, wherein the rotating handle comprises:
a rotating disk comprising a top wall, a side wall and a recessed portion, wherein the recessed portion is formed in the bottom of the rotating disk, and the profile of the recessed portion matches the shaft portion of the holder frame; and
a handle component disposed on the top wall.

5. The press-fit module according to claim 4, wherein the handle component comprises:
a rotation shaft disposed on the top wall;
a first locking element disposed on the top wall and spaced apart from the rotation shaft by a predetermined distance;
a grip comprising a first end and a second end;
wherein the first end of the grip is movably connected to the rotation shaft, and the second end of the grip is a free end and comprises a second locking element;
wherein the grip is switchable between a first state and a second state, when in the first state, the second locking element of the grip engages with the first locking element; when in the second state, the second locking element of the grip is disengaged from the first locking element.

6. The press-fit module according to claim 5, wherein the rotating disk comprises a first magnetic element disposed on the top wall of the rotating disk, and the grip comprises a second magnetic element disposed corresponding to the first magnetic element, wherein when the grip is in the first state, the first magnetic element is magnetically coupled with the second magnetic element.

7. The press-fit module according to claim 4, wherein the rotating disk of the rotating handle comprises a track groove formed in the bottom side of the side wall of the rotating disk, and the carrier device comprises a guide post disposed on the upper base surface of the holder frame, wherein the guide post is accommodated in the track groove of the rotating handle, and configured to limit the range of the rotation angle of the rotating handle.

8. The press-fit module according to claim 4, wherein the rotating disk comprises a connecting component disposed on the recessed portion, wherein the connecting component comprises a plurality of connecting holes and a plurality of fastening elements, the plurality of connecting holes penetrate through the rotating disk, and the connecting shaft of the cam follower comprises a plurality of locking holes, wherein each fastening element extends through the corresponding connecting hole, and engages with the corresponding locking hole of the connecting shaft.

9. The press-fit module according to claim 1, wherein the carrier device comprises at least one first positioning element disposed on a lower base surface of the base of the holder frame, wherein the cam follower comprises at least one second positioning element disposed on the upper disk surface of the rotating disk, and the at least one first positioning element and the at least one second are detachably engaged with each other.

10. The press-fit module according to claim 9, wherein the holder frame of the carrier device comprises at least one opening formed in the lower base surface of the holder frame, wherein each first positioning element is disposed in a corresponding opening, and comprises a cylinder, a ball and a second elastic element, wherein the cylinder comprises an accommodating recess, the second elastic element is disposed within the accommodating recess, and is elastically connected between the bottom of the accommodating recess and the ball, wherein at least a portion of the ball protrudes from the accommodating recess and extends beyond the opening of the holder frame, wherein when the ball rolls to the position of the second positioning element, the ball is engaged with the second positioning element.

11. The press-fit module according to claim 9, wherein the second positioning element is a positioning recess, and comprises a first inclined surface and a second inclined surface, wherein the first inclined surface and the second inclined surface form a V-shaped groove structure.

12. The press-fit module according to claim 2, wherein the holder frame comprises a plurality of openings penetrating through the upper base surface and a lower base surface, and each opening comprises a first segment, a second segment and an abutment surface, wherein the first segment is connected between the upper base surface and the second segment, the second segment is connected between the first segment and the lower base surface, wherein the diameter of the first segment is greater than the diameter of the second segment, and the abutment surface is formed between the first segment and the second segment, wherein the heat dissipation device comprises a plurality of fasteners and a plurality of third elastic elements, each fastener penetrates through a corresponding opening and comprises a rod portion and a head portion, wherein the diameter of the rod portion is smaller than the diameter of the second segment, wherein an end of the rod portion is connected to the side wall of the heat dissipation device, and the other end of the rod portion is connected to the head portion, wherein the diameter of the head portion is greater than the diameter of the second segment, but smaller than that of the first segment, wherein each third elastic element is sleeved around the rod portion of the corresponding fastener, and disposed within the first segment of the opening, wherein an end of the third elastic element abuts against the bottom of the head portion, and the other end of the third elastic element abuts against the abutment surface.

13. The press-fit module according to claim 3, wherein the cam pushing unit comprises a plurality of first limiting elements disposed on a lower plate body surface of the plate body, wherein each first limiting element comprises a rod portion and a head portion, an end of the rod portion is connected to the head portion, and the other end of the rod portion is connected to the lower plate body surface, wherein the diameter of the head portion is greater than the diameter of the rod portion, wherein the heat dissipation device comprises a plurality of second limiting elements, wherein each second limiting element penetrates through the bottom plate, and comprises a first segment, a second segment and an abutment surface, wherein the diameter of the first segment is smaller than the diameter of the second segment, and the abutment surface is disposed between the first segment and the second segment, wherein each first limiting element penetrates through the corresponding second limiting element, at least a portion of the rod portion is movably disposed in the first segment of the second limiting element, and the head portion is movably disposed within the second segment of the second limiting element.

14. A press-fit test device for testing an electronic device, comprising:
a mount comprising a test module; and
a press-fit module disposed on the mount and comprising:
a rotating handle;
a carrier device comprising a holder frame, wherein the holder frame comprises a base, a shaft portion, and a through hole, wherein the shaft portion is disposed on an upper base surface of the base, and the through hole penetrates through the shaft portion, wherein the rotating handle covers the shaft portion; and
a pressing structure comprising a cam follower and a cam pushing unit, wherein the cam follower comprises a rotating disk and a connecting shaft, wherein at least two rollers are disposed on a lower disk surface of the rotating disk, the connecting shaft is connected to the rotating handle through the through hole, wherein the cam pushing unit is movably connected to the lower disk surface, and comprises a plate body and at least two guide structures, wherein the at least two guide structures are disposed on an upper plate body surface of the plate body, and are corresponded to the at least two rollers, respectively, wherein each guide structure comprises a sequential connection of a first flat structure, an inclined structure, and a second flat structure;
wherein when the rotating handle is rotated, the rotating handle drives the cam follower to rotate accordingly, each roller of the cam follower rolls from the first flat structure of the corresponding guide structure to the second flat structure via the inclined structure, thereby pushing the cam pushing unit to move in the direction away from the cam follower;
wherein the electronic device is positioned between the press-fit module and the test module of the base, wherein when the cam pushing unit moves away from the cam follower, the cam pushing unit applies a pressing force to the electronic device, forcing the electronic device against the test module to establish an electrical connection, thereby generating test signals and enabling test execution of the electronic device.

15. The press-fit test device according to claim 14, wherein the mount comprises a main body comprising a second accommodating space, wherein the test module is disposed in the second accommodating space, and comprises a plurality of test probes and a test board, wherein the plurality of test probes are electrically connected to the test board, and are configured to contact the plurality of pins of the electronic device.

16. The press-fit test device according to claim 14, wherein the holder frame of the carrier device comprises a first latching element, and the mount comprises a second latching element, wherein the first latching element and the second latching element are engaged with each other.
